(19) United States
(12) Patent Application Publication
(10) Pub. No.: US 2010/0224715 A1
(43) Pub. Date: Sep. 9, 2010

(54) WIRE SUPPLY DEVICE FOR A WIRE BONDER

(75) Inventor: Armin Felber, Luzern (CH)

Correspondence Address: MCCORMICK, PAULDING & HUBER LLP, CITY PLACE II, 185 ASYLUM STREET, HARTFORD, CT, 06103, US

(73) Assignee: OERLIKON ASSEMBLY EQUIPMENT AG, STEINHAUSEN, CHAM (CH)

(21) Appl. No.: 12/303,978

(22) PCT Filed: Jun. 4, 2007
(86) PCT No.: PCT/EP07/55432

§ 371 Date: Dec. 9, 2008

(30) Foreign Application Priority Data
Jun. 14, 2006 (CH) 00986/06

(51) Int. Cl. B65H 59/10; H01L 21/00

(52) U.S. Cl. 242/419.3

(57) ABSTRACT

A device for supplying a wire from a wire roll to a capillary of a wire bonder comprises a holder, driven by a motor, for a wire roll and a wire store. The wire store comprises a plurality of channels that can be loaded with compressed air and the exit apertures of which are located on a circular arc and span a predetermined angle range and which run in a substantially radial direction with respect to the center of the circular arc, in order that the wire runs substantially along a circular path within the predetermined angle range.

### CROSS REFERENCE TO RELATED APPLICATIONS

The present application is related to and claims priority of the PCT application number PCT/EP2007/055432 filed Jun. 4, 2007, the disclosure of which is herein incorporated by reference, which in turn claims priority of the Swiss patent application number 986/06 filed Jun. 14, 2006.

### FIELD OF THE INVENTION

The invention relates to a wire supply device for a wire bonder.

### BACKGROUND OF THE INVENTION

A wire bonder is a machine with which semiconductor chips are wired after mounting on a substrate. The wire bonder has a capillary that is clamped to the tip of a horn. The capillary serves to secure the wire to a connection point on the semiconductor chip and to a connection point on the substrate as well as to guide the wire between the two connection points. On producing the wire connection between the connection point on the semiconductor chip and the connection point on the substrate, the end of the wire protruding out of the capillary is first melted into a ball. Afterwards, the wire ball is secured to the connection point on the semiconductor chip by means of pressure and ultrasonics. In doing so, ultrasonics is applied to the horn from an ultrasonic transducer. This process is called ball bonding. The wire is then pulled through to the required length, formed into a wire loop and welded to the connection point on the substrate. This last part of the process is called wedge bonding. After securing the wire to the connection point on the substrate, the wire is torn off and the next bonding cycle can begin.

The wire is wound on a wire roll. The wire is supplied to the capillary by a wire supply device. FIG. 1 shows a wire supply device of this type. The wire supply device comprises a holder 2, driven by the shaft 1 of a motor, for the wire roll 3 and a wire store 4, operating with compressed air, with a sensor 5. The wire store 4 comprises a leading plate and a trailing plate 6 which are arranged parallel to each other at a predetermined spacing of about 0.2 mm. The leading plate is omitted in the drawings. The trailing plate 6 contains elevations 7 on which the leading plate rests. The predetermined spacing between the two plates is thus fixed. The wire 8 is supplied to the wire store 4 from the side and leaves the wire store 4 in an approximately vertical direction. A channel 9 is formed between the plates by an additional indentation provided in the trailing and leading plates, through which channel compressed air flows in the direction illustrated by arrows. The compressed air deflects the wire 8. The maximum deflection of the wire 8 is delimited by stops 10 and 11. The sensor 5 is situated at the stop 10. The sensor 5 is an optical sensor with a light transmitter and a light receiver. The light transmitter emits a light beam and the light receiver measures whether light reflected on the wire 8 falls back onto it. The edge of the region within which the wire 8 is situated during normal operation is illustrated by broken lines 13. In order that the course of the wire is independent of the extent of unwinding of the wire 8 from the wire roll 3, a pin 15, which deflects the wire 8, is also arranged between the wire roll 3 and the wire store 4.

An additional wire tensioning device 16 is arranged between the wire store 4 and the capillary 14 and substantially comprises a small tube through which air is blown in the direction of the arrow shown next to the wire tensioning device 16, in order to keep the wire taut in the region of a wire clamp 17 arranged above the capillary 14.

During bonding either wire is consumed, that is to say if the wire loop is formed and therefore wire is drawn out of the wire store 4, or wire is recoiled into the wire store 4, that is to say if the capillary 14 is raised to form a new wire ball.

The wire 8 is not continuously unwound at constant speed but unwound as required from the wire roll 3 in a manner controlled by the sensor 5. Whenever the output signal of the sensor 5 indicates that the wire 8 has left the measuring range of the sensor 5 the motor rotates the wire roll 3 until the output signal of the sensor 5 indicates that the wire 8 is in the measuring range of the sensor 5 again.

The air flowing in the channel 9 deflects the wire 8 and thus generates a tension force in the wire. The drawback of this wire store 4 lies in the fact that the tension force is highly dependent on the current course of the wire 8 within the wire store 4 or the current quantity of wire stored in the wire store, and this can lead to varying wire heights (called “loop heights” among experts). These variations are also strongly non-linear for geometric reasons.

### SUMMARY OF THE INVENTION

The object underlying the invention is to develop a device and a method for supplying a wire in the case of a wire bonder, comprising a wire store, in which the tension force of the wire is as independent as possible from the current quantity of wire stored in the wire store.

According to the invention the compressed air in the wire store is blown onto the wire in such a way that the wire runs substantially along a circular path in a predetermined angular range. Regardless of whether the wire store is currently receiving a minimum quantity or maximum quantity of wire, or any desired quantity in between, the wire always runs approximately on a circular path; only the radius thereof changes. The quantity of wire instantaneously accommodated by the wire store does not have any appreciable effect on the tension force in the wire therefore.

A device for supplying wire from the wire roll to the capillary of the wire bonder comprises a holder, driven by a motor, for receiving the wire roll and a wire store. The wire store according to the invention comprises two plates that are arranged so as to be spaced apart and between which a plurality of channels are formed of which the outlet apertures are located on a circular arc and which, with respect to the center of the circular arc, run in a substantially radial direction. The channels cover an angular range φ. During operation the channels are loaded with compressed air which thus flows in the radial direction and tensions the wire. The wire runs substantially along a circular path within the angular range φ. The angular range φ is typically 150° to 180°, however at least 90°. The number of channels is preferably at least φ/30°.

At the entrance to the wire store and at the exit from the wire store there is preferably arranged a respective pin at which the wire is deflected during operation, or the wire store itself is constructed in such a way that during operation the wire is deflected at a predetermined location at the entrance to the wire store and at a predetermined location at the exit from the wire store. This results in the direction in which the wire enters the wire store and the direction in which the wire exits the wire store being independent of the length of the wire received in the wire store. The tension force in the wire is thus largely independent of the length of the wire received in the wire store.

### BRIEF DESCRIPTION OF THE DRAWING FIGURES

The accompanying drawings, which are incorporated into and constitute a part of this specification, illustrate one or more embodiments of the present invention and, together with the detailed description, serve to explain the principles and implementations of the invention. The figures are not to scale.

In the drawings:

FIG. 1 shows in a top view a wire supply device according to the prior art,

FIG. 2 shows in a top view an embodiment of a wire supply device with a wire store according to the invention, and

FIG. 3 shows in cross-section the wire store according to the invention.

### DETAILED DESCRIPTION

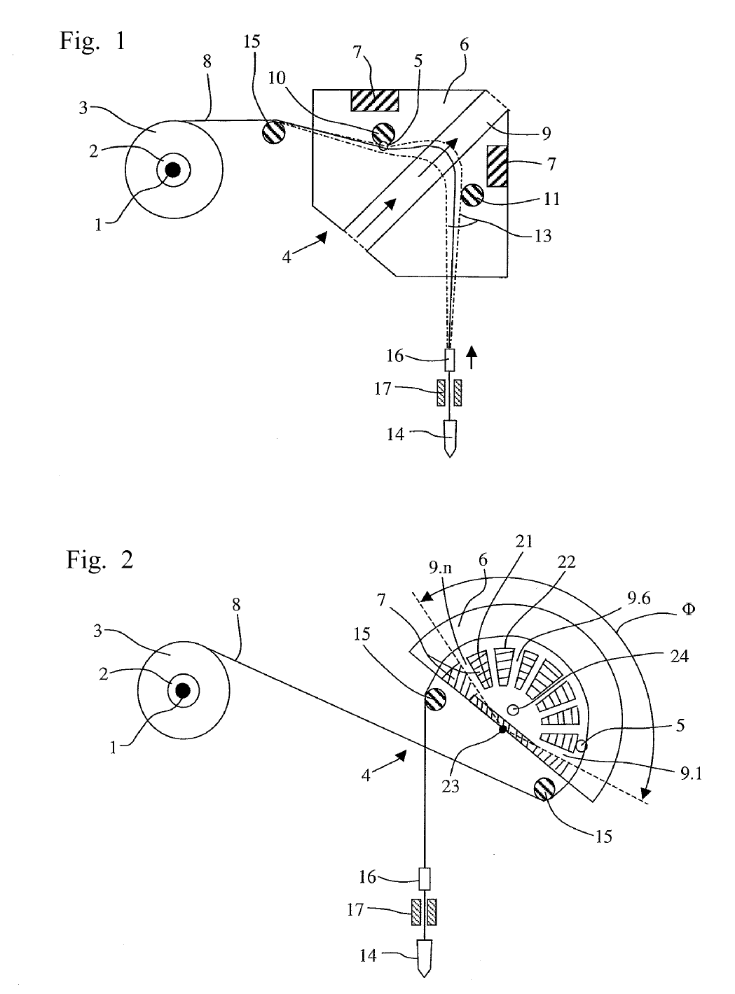

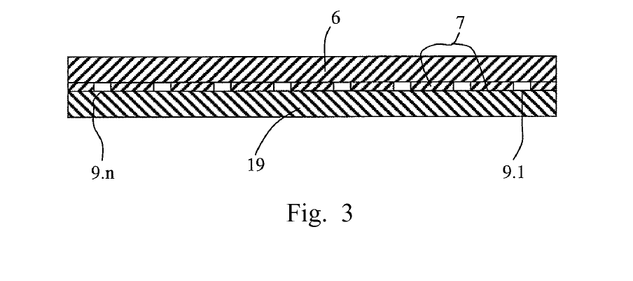

A wire supply device comprises the components already illustrated in FIG. 1, namely the holder 2, driven by a motor and which receives the wire roll 3, and the wire store 4. The wire store 4 is improved however such that the tension force in the wire 8 is much less dependent on the current position of the wire 8. The invention substantially lies in allowing the air to flow in the wire store 4 in such a way that the wire within the wire store 4 runs along a circular path. The wire store 4 in turn comprises the leading plate 19 (FIG. 3) and the trailing plate 6 which are arranged parallel to each other at a predetermined spacing. The predetermined spacing is about 0.1 to 0.3 mm, typically 0.2 mm. One of the two plates 6 and 19, the leading plate 19 in the example, is a flat plate without indentations. FIG. 2 shows in a top view the wire supply device, the leading plate 19 of the wire store 4 being omitted. FIG. 3 shows the wire store 4 in cross-section along the circle 22 of FIG. 2. The trailing plate 6 contains a plurality of planar elevations 7 between which a number n of channels 9.1 to 9.n are formed (in the example n=8). The ends of the channels 9.1 to 9.n rest on two concentric circles 21 and 22 with center 23. The exit apertures of the channels 9.1 to 9.n therefore rest on a circular arc. The center 23 is on the one hand the middle point of the circular arc and on the other hand a reference point, with respect to which the channels 9.1 to 9.n run in the radial direction. Within the inner circle 21 is a hole 24 through which compressed air is supplied. If the leading plate 19 is secured to the trailing plate 6 a cavity limited by the elevations 7 and the entrance apertures of the channels 9.1 to 9.n is formed in the region of the hole 24 and is connected by the channels 9.1 to 9.n to the surroundings. The air flowing through the channels 9.1 to 9.n in the radial direction presses the wire 8 outwards at several locations and thus produces a tension force in the wire 8. The wire 8 runs substantially on a circular path in the angular range φ defined by the two outermost channels 9.1 and 9.n, the path being concentric to the circles 21 and 22. In this example the angular range is about 145°.

The sensor 5 is preferably the same sensor as in the wire supply device according to FIG. 1 and unwinding of the wire 8 from the wire roll 3 again takes place in a manner controlled by the sensor 5.

The angular range φ defined by the two outermost channels 9.1 and 9.n is advantageously at least 90°. It may also be bigger however and be for example, as in the example of FIG. 2, about 145° or even more than 180°, for example 240°. The tension force produced in the wire 8 increases as the angular range φ increases. The tension force may therefore be increased or reduced via the size of the angular range φ.

A pin 15 is preferably arranged at the entrance to the wire store 4 and a pin 15 is preferably arranged at the exit from the wire store, at which pins the wire is deflected during operation. Because the wire is deflected at the pins 15 it always rests against the pins 15. The edges of the pin 15 also lie on the outer concentric circle 22 or at least relatively close to the outer concentric circle 22. The two pins 15 may also be omitted if their function is fulfilled by the two outermost elevations 7 which delimit the outer side of the two outermost channels 9.1 and 9.n of the trailing plate 6, that is to say if the construction of the outermost elevations 7 is configured in such a way that the wire 8 cannot get stuck on these elevations 7. In this case the wire rests directly on the entrance to the wire store 4 and directly on the exit from the wire store 4.

In the example of FIG. 2 the wire 8 is guided by means of pins 15 in such a way that the wire 8 crosses at one point. The two pins 15 or more than two pins 15 may also be positioned in such a way that the wire 8 is supplied to the wire store 4 and is led away from the wire store 4 without crossing of the wire.

While embodiments and applications of this invention have been shown and described, it would be apparent to those skilled in the art having the benefit of this disclosure that many more modifications than mentioned above are possible without departing from the inventive concepts herein. The invention, therefore, is not to be restricted except by the appended claims.

1. Wire supply device for supplying a wire to a capillary of a wire bonder, the wire supply device comprising
a holder for receiving a wire roll,
a motor for driving the holder, and
a wire store, the wire store comprising a plurality of channels loadable with compressed air, the exit apertures of the channels being located on a circular arc and the channels running in a substantially radial direction with respect to the center of the circular arc.

2. Wire supply device according to claim 1, wherein an angular range, φ, spanned by the circular arc amounts to at least 90° and wherein the number of channels is at least φ/30°.

3. Wire supply device according to claim 1, wherein a pin is arranged at the entrance to the wire store and a pin is arranged at the exit from the wire store at which pins the wire is deflected during operation.

4. Wire supply device according to claim 2, wherein a pin is arranged at the entrance to the wire store and a pin is arranged at the exit from the wire store at which pins the wire is deflected during operation.

5. Wire supply device according to claim 1, wherein during operation the wire is deflected at a predetermined location at the entrance to the wire store and at a predetermined location at the exit from the wire store.

6. Wire supply device according to claim 2, wherein during operation the wire is deflected at a predetermined location at the entrance to the wire store and at a predetermined location at the exit from the wire store.
